(19) United States
(12) Patent Application Publication
(10) Pub. No.: US 2019/0139722 A1
(43) Pub. Date: May 9, 2019

(54) BACKLIGHT KEYBOARDS

(71) Applicant: HEWLETT-PACKARD DEVELOPMENT COMPANY, L.P., HOUSTON, TX (US)

(72) Inventors: HUNG-MING CHEN, TAIPEI CITY (TW); KUAN-TING WU, TAIPEI CITY (TW); CHAO-WEN CHENG, TAIPEI CITY (TW)

(21) Appl. No.: 16/092,944

(22) PCT Filed: Jul. 26, 2016
(86) PCT No.: PCT/US2016/043972

§ 371 Date: Oct. 11, 2018

(51) Int. Cl. H01H 13/83; G06F 3/02; F21V 8/00; H05K 1/03

(52) U.S. Cl. CPC H01H 13/83; G06F 3/0202; G02B 6/0068; G02B 6/0073; G02B 6/0083; H05K 1/0313; H01H 2219/044; H05K 2201/0329; H05K 2201/10106; H05K 2201/10121; H01H 2219/06; H01H 2219/062; H01H 2219/037; G02B 6/005

(57) ABSTRACT

The present subject matter relates to backlight keyboards. In an example implementation of the present subject matter, backlight keyboards and methods of fabricating lighting units for such backlight keyboards are described. In an example, a backlight keyboard includes a substrate and a plurality of Light Emitting Diodes (LEDs) disposed on the substrate. The backlight keyboard further includes a printed circuit disposed on the substrate, where the printed circuit comprises of a plurality of electrical connections to provide electric current to the plurality of LEDs, and where width of each of the plurality of electrical connections is predefined to control brightness of a corresponding LED from amongst the plurality of LEDs.

### BACKGROUND

Devices, such as computers and mobile phones, have a keyboard as an input device. The keyboard may be coupled as a peripheral device or may be integrated with such devices. The keyboard of a computer or a mobile phone may be a backlight keyboard in which light is transmitted from a backlight plane through keycaps in the keyboard.

### BRIEF DESCRIPTION OF DRAWINGS

The following detailed description references the drawings, wherein:

FIG. 1 illustrates a lighting unit for a backlight keyboard, according to an example implementation of the present subject matter;

FIG. 2 illustrates a backlight keyboard implementing a lighting unit, according to an example implementation of the present subject matter;

FIG. 3 illustrates a sectional view of lighting unit, according to an example implementation of the present subject matter; and

FIG. 4 illustrates a method of manufacturing a lighting unit for a backlight keyboard, according to an example implementation of the present subject matter.

### DETAILED DESCRIPTION

Backlight keyboards in computers and mobile phones help users to identify keyboard keys while typing in low-light or dark ambient environments. A backlight keyboard has a lighting unit, and, keyboard keys that transmit light coming from the lighting unit. The lighting unit generally includes multiple light emitting diodes (LEDs) arranged on a substrate, along with an electric circuit including different electrical connections to provide electrical current to the LEDs. The electric circuit is generally etched onto the substrate of the lighting unit. The substrate of the lighting unit, such as a Flexible printed circuit (FPC) board, generally includes etched copper circuits to supply electric current to the multiple LEDs. Techniques such as lithography and etching are employed to form the etched copper circuits which are costly, and lead to higher production cycle time for the backlight keyboards. Moreover, the use of lithographic process causes environmental damage due to use of toxic chemicals to form the copper circuits.

Further, different LEDs arranged on the substrate of the lighting unit have different operating brightness. Therefore, the electric circuit of the lighting unit generally includes separate resistors along with the electrical connections, to achieve uniform brightness among all LEDs. The inclusion of separate resistors on the substrate, along with the electrical connections, consumes space on the substrate, and increases the time and cost of production of the backlight keyboards.

According to an example implementation of the present subject matter, resistor-free printed lighting units for backlight keyboards are described. In an example implementation of the present subject matter, the lighting unit includes an electric circuit, printed on a substrate of the lighting unit. For the ease of reference, the electric circuit printed on the substrate is also referred to as a printed circuit, hereinafter.

The printed circuit may include electrical connections on the substrate of the lighting unit to supply electric current to the LEDs. In an example implementation, each electrical connection to each LED, may be formed of a predefined width, to control electric resistance of the electrical connection to the LED. Further, the electrical connections may be formed of a conductive material that has increased resistance than that of conductors such as copper, to avoid usage of separate resistor for each LED.

The predefined width of each of the electrical connection may provide different resistance to the corresponding LEDs and may therefore be utilized for controlling uniform brightness among all the LEDs. For example, one LED may be connected to an electrical connection of width ‘x’ based on the resistance requisite for uniform brightness. Further, another LED may be connected to an electrical connection of width ‘2.5*x’ based on the resistance requisite for the uniform brightness. Similarly, another LED of the lighting unit may be connected to an electrical connection of width ‘0.8*x’, based on the resistance requisite for the uniform brightness. Therefore, depending on the operating brightness of each LED, the width of different electrical connections to each LED may be predefined.

Therefore, the use of printed circuits made of increased resistance conductive material along with predefined widths for each LED may reduce the production time of the lighting unit, and may also reduce the cost of the backlight keyboards.

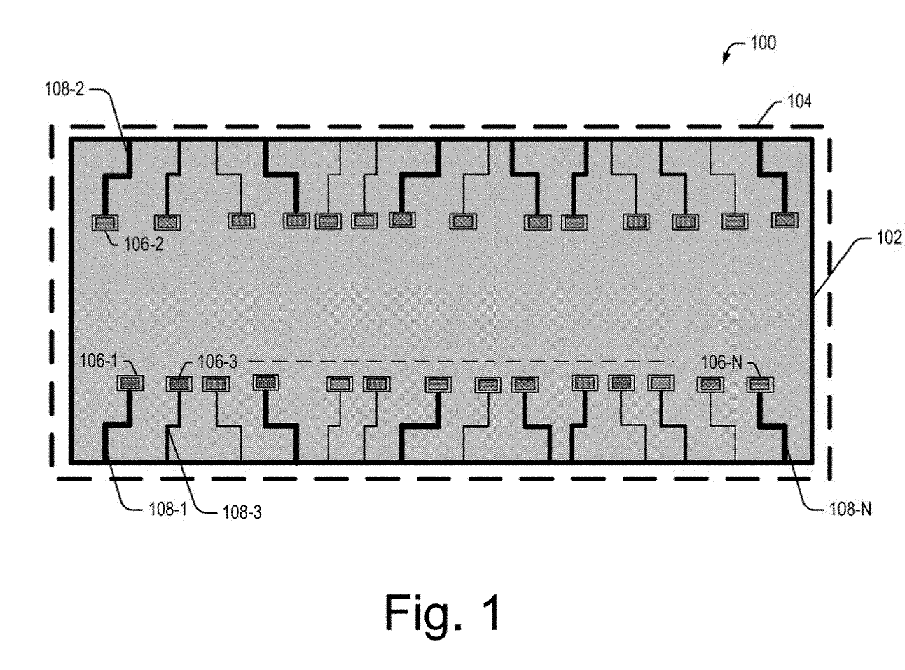

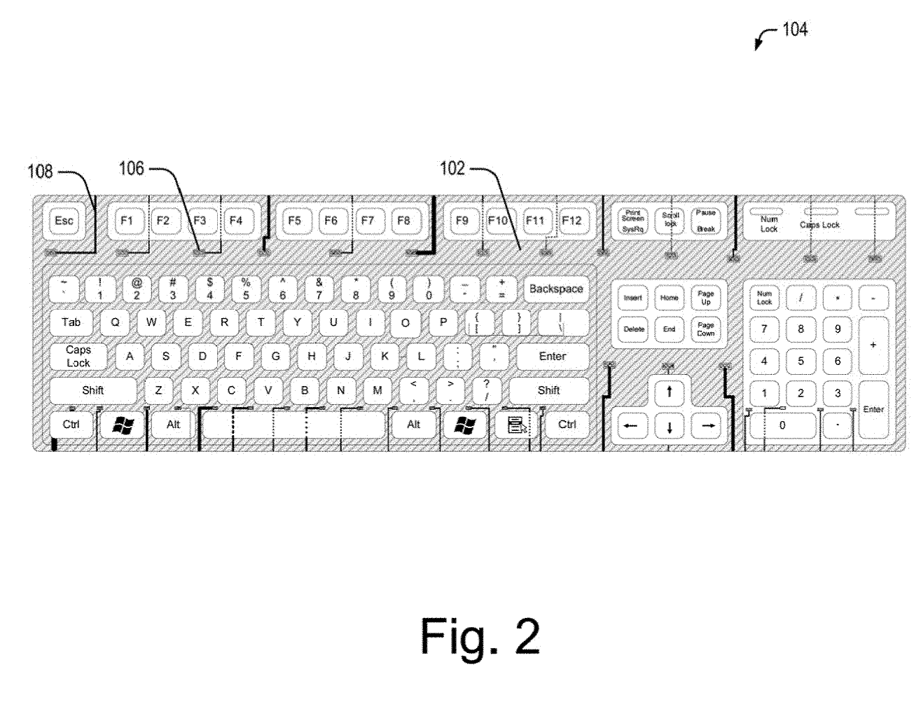

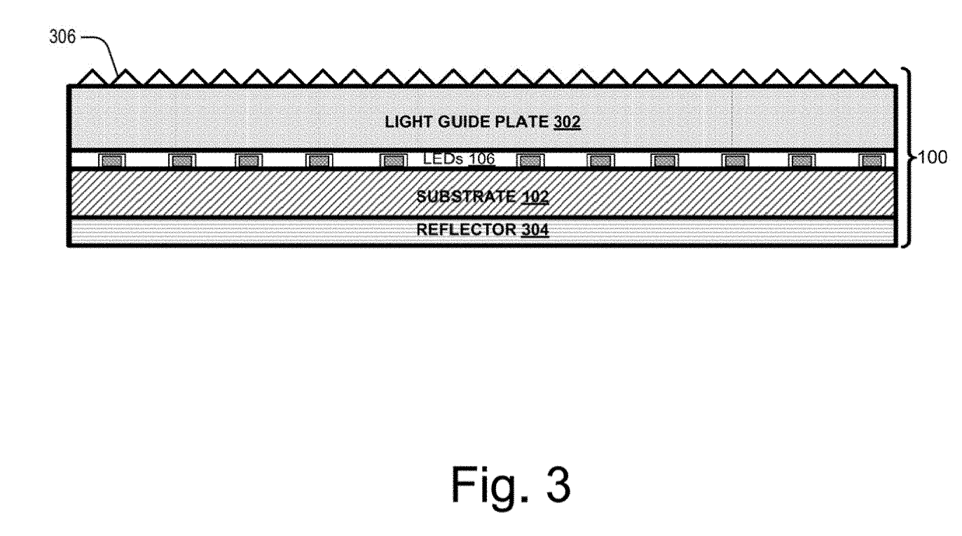

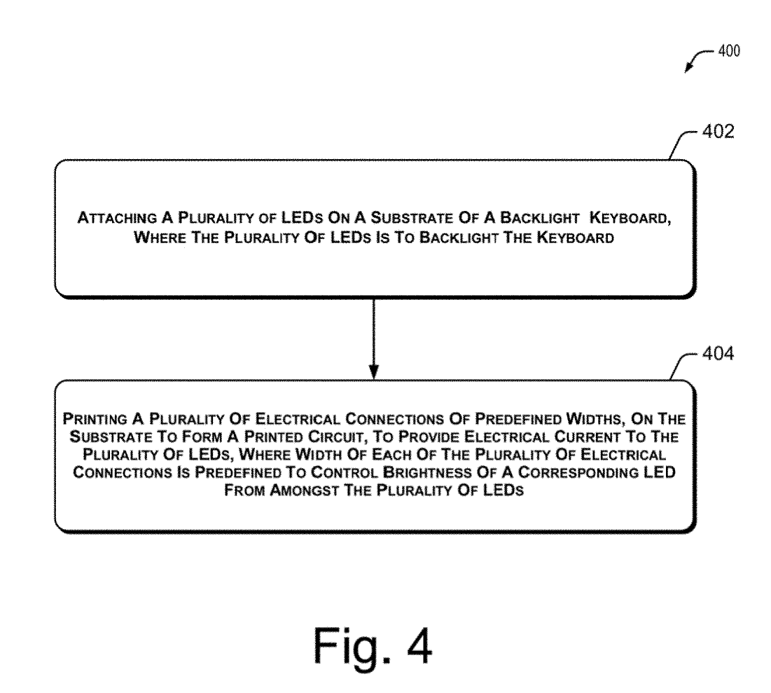

The above techniques are further described with reference to FIG. 1, FIG. 2, FIG. 3, and FIG. 4. It should be noted that the description and the figures merely illustrate the principles of the present subject matter along with examples described herein, and should not be construed as a limitation to the present subject matter. It is, thus understood that various arrangements may be devised that although not explicitly described or shown herein, embody the principles of the present subject matter. Moreover, all statements herein reciting principles, aspects, and implementations of the present subject matter, as well as specific examples thereof, are intended to encompass equivalents thereof.

FIG. 1 illustrates a lighting unit 100 fora backlight keyboard, according to an example implementation of the present subject matter. The lighting unit 100 may include a substrate 102, which may fit beneath the keys and structure of a backlight keyboard 104. The substrate 102 may include multiple LEDs 106-1, 106-2, 106-3, . . . , 106-N, arranged at different locations for lighting the backlight keyboard 104. Further, the substrate 102 may also include electric circuit including multiple electrical connections 108-1, 108-2, 108-3, . . . , 108-N. For the ease of explanation, the LEDs 106-1, 106-2, 106-3 . . . , 106-N have been commonly referred to as LEDs 106, and the electrical connections 108-1, 108-2, 108-3, . . . , 108-N have been commonly referred to as electrical connections 108, hereinafter.

In an example of the present subject matter, the substrate may be formed of any known insulating material, such as FR-2 (phenolic cotton paper), FR-3 (cotton paper and epoxy), FR-4 (woven glass and epoxy). FR-5 (woven glass and epoxy), FR-6 (matte glass and polyester), G-10 (woven glass and epoxy), CEM-1 (cotton paper and epoxy). CEM-2 (cotton paper and epoxy), CEM-3 (non-woven glass and epoxy), CEM-4 (woven glass and epoxy), CEM-5 (woven glass and polyester), and polyethylene terephthalate (PET).

Further, the substrate 102 may be any one of a single-sided, double-sided, multi-layer, aluminum-backed, flexible, rigidized flexible, and flexi-rigid substrate.

In an example, the substrate 102 may be a flexible circuit board and may allow printing of electric circuits. For the ease of explanation, the electric circuit printed in the substrate 102 has been referred to as printed circuit hereinafter. In an example, the printed circuit may be formed by utilizing any known form of printing, such as inkjet printing, rotogravure printing, 3D printing, and laser engraving printing.

As described, the substrate 102 may be placed within a backlight keyboard 104. The backlight keyboard 104 may be an external keyboard used along with a desktop computer or any other computing device, or may be an integrated keyboard included in a portable computing device, such as a laptop, a personal digital assistant (PDA), a mobile phone, a smartphone, and a cordless phone. Further, the backlight keyboard 104 may also be included in panels of home appliances, such as washing machines, refrigerators, air conditioners, dishwashers, and microwave ovens. It would be noted that the backlight keyboard 104 may be included with a range of electronic devices, and may not be limited to QWERTY keyboards utilized along with computers.

The LEDs 106 disposed on the substrate 102 may be placed at different location on the substrate 102, depending on the backlighting requisite for the backlight keyboard 104. For example, in one implementation, the LEDs 106 may be placed all across the substrate 102 to uniformly backlight the backlight keyboard 104. However, in another example implementation, the LEDs 106 may be placed along the edges of the substrate 102 to light the backlight keyboard 104 along the edges. Therefore, depending on the lighting requisite of the backlight keyboard 104, the LEDs 106 may be disposed on the substrate 102. In an example implementation of the present subject matter, the LEDs 106 may include a combination of any of the edge-lit LEDs, direct LEDs, and organic light-emitting diodes (OLEDs).

As described earlier, the printed circuit may be printed on the substrate 102. In an example implementation of the present subject matter, the printed circuit may include multiple electrical connections 108, such that each electrical connection 108 is to provide electric current to one LED 106. For example, the electrical connection 108-1 nay be formed such that the LED 106-1 may be provided with the requisite electrical current. It would be noted that the electrical connections 108 may be printed on the substrate 102 based on the placement of the LEDs 106 on the substrate 102.

According to an example implementation of the present subject matter, each electrical connection 108, may be formed of a predefined width, depending on the LED 106 to which it is connected to. That is, depending on the resistance requisite of the LED 106, to operate on a uniform brightness, the electrical connection 108 may be formed of a predefined width.

For example, the width of the electrical connection 108-1 may be predefined to ‘x’ millimeters (mm) based on the resistance requisite of the LED 106-1, to operate on a defined brightness. Similarly, if the LED 106-3 may requisite for a higher resistance for providing the defined brightness, the electrical connection 108-3 may be formed of ‘1.75x” mm. Therefore, the width of the electrical connections 108 may be predefined based on resistance requisite of the corresponding LEDs 106.

Although the widths of the different electrical connections 108 have been described to be predefined, it would be noted that the electrical connections 108 may have similar widths in situations where the requisite of resistance of the LEDs 106, for providing the defined brightness is similar.

In an example implementation of the present subject matter, the electrical connections 108 may be formed by printing a conductive material onto the substrate 102. For example, any electrical conductor, such as metals, electrolytes, superconductors, semiconductors, plasmas, conductive polymers, and nonmetallic conductors such as graphite, may be utilized as the conductive material for the electrical connections 108.

In an example implementation, the conductive material utilized for the electrical connections 108 may include higher resistance than that of metallic conductors such as copper. For example, conductive polymers such as poly (3,4-ethylenedioxythiophene) polystyrene sultanate, Polyacetylene, and Polyaniline may be utilized to form the electrical connections 108. The use of conductive polymers in the electrical connections 108 may allow easy and efficient printing of these materials onto the substrate 102, and may provide requisite resistance to each electrical connection 108.

An electrical connection 108 made from poly (3,4-ethylenedioxythiophene) polystyrene sulfonate may provide easy printing capability onto the substrate 102 and may provide good electrical conductivity. Further, poly (3,4-ethylenedioxythiophene) polystyrene sulfonate may provide higher resistance than that of conductive metals, such as copper that may allow providing requisite resistance to LEDs 106, by predefining the widths of the electrical connections 108.

In an example implementation of the present subject matter, materials such as silver nanowire, carbon nanotube and graphene may also be utilized as the conductive material for the electrical connections 108. The use of silver nanowire, or carbon nanotube may also provide easy printing capability onto the substrate 102 and may provide good electrical conductivity.

FIG. 2 illustrates top view of a backlight keyboard 104, according to an example implementation of the present subject matter. The backlight keyboard 104 may comprise of a lighting unit 100 (not shown) including the substrate 102. The substrate 102 may include a printed circuit having multiple electrical connections 108. The electrical connections 108 may be connected to multiple LEDs 106, where the width of each electrical connection 108 is based on resistance requisite of a corresponding LED to which it is connected to. It would be noted that the resistance requisite of the LEDs 106 may be based on the requisite brightness from the LEDs 106. And therefore, depending on the brightness requisite from the LEDs 106, the requisite resistance for each LED may vary, and accordingly, the predefined width of each electrical connection 108 may vary.

In an example implementation of the present subject matter, the electrical connections 108 may be printed in the substrate 102 such that the backlight keyboard 104 is lighted in between the keys. As described earlier, the LEDs 106 may also be arranged at different locations, such as edges of the backlight keyboard 104 or under each key of the backlight keyboard 104. Accordingly, the electrical connections 108 may also be printed on the substrate 102.

In reference to FIG. 2, each electrical connection 108, connected to a corresponding LEDs 106, is of a predefined width. Further, although the LEDs 106 have been depicted to be arranged at the top and bottom of the backlight keyboard 104, it would be noted that the LEDs 106 may be placed beneath the keys of the backlight keyboard 104.

Also, while a QWERTY backlight keyboard has been depicted in FIG. 2, it would be noted that the described lighting unit 100 may be implemented in any keyboard utilized with a computing system, a communication device, and an, electronic appliance.

FIG. 3 illustrates a sectional view of a lighting unit, such as the lighting unit 100, according to an example implementation of the present subject matter. The lighting unit 100 may include the substrate 102 and the multiple LEDs 106 disposed over the substrate 102. In an example implementation of the present subject matter, the substrate 102 may further include a light guide plate 302 disposed over the LEDs 106 and the printed circuit (not shown).

In an example, the light guide plate 302 may be disposed to control efficiency of the lighting unit 100. The light guide plate 302 may guide the light emitted by the LEDs 106 is a uniform manner to light the backlight keyboard 104 efficiently. In an implementation, the light guide plate 302 may be made of any one of polymethylmethacrylate (PMMA), polycarbonate, and cyclic olefin copolymer (COC).

The lighting unit 100 may also include a reflector 304 disposed beneath the substrate 102, to reflect any light being dispersed towards the substrate 102. The presence of the reflector may increase the light available for the backlighting, thereby increasing the overall brightness of the lighting unit 100.

In an example implementation of the present subject matter, the lighting unit 100 may also include a light scattering pattern 306 formed over the light guide plate 302, to uniformly scatter the light being emitted by the light guide plate 302. The light scattering pattern 306 may be formed over the light guide plate 302 through any of the known printing techniques, such as a screen printing technique, an ultra-violet (UV) based imprinting technique, an ink-jet printing technique, a rotogravure printing technique, 3D printing technique, and a laser engraving technique.

Therefore, the light guide plate 302, the reflector 304 along with the light scattering pattern 306 may allow the lighting unit 100 to direct the light emitted by the LEDs 106 towards the front of the backlight keyboard 104, thereby providing efficient and effective backlighting to the backlight keyboard 104.

The use of the printed circuits which can be formed by known printing techniques, such as screen printing, allow reduction in cost of production of the lighting units for backlight keyboards. Further, the use of predefined widths for electrical connections to the LEDs may allow for elimination of use of resistors in the electrical circuits. And therefore, the described lighting units may provide uniform brightness, without the utilization of separate resistors.

FIG. 4 illustrates a method 400 of fabricating lighting units for a backlight keyboard, in accordance to an example implementation of the present subject matter. The order in which the method 400 is described is not intended to be construed as a limitation, and any number of the described method blocks may be combined in any order to implement the method 400, or any alternative methods. Furthermore, the method 400 may be implemented by electronic circuits, or processor(s) through any suitable hardware, or combination thereof for fabrication of the lighting units.

At block 402, a plurality of LEDs are attached on a substrate of the backlight keyboard, wherein the plurality of LEDs is to backlight the keyboard. The LEDs may be attached at different location on the substrate, based on the layout and configuration of the backlight keyboard. For example, the LEDs may be arranged such that they lie beneath the keys of the backlight keyboard.

At block 404, a plurality of electrical connections of predefined widths are printed on the substrate to form a printed circuit and provide electrical current to the plurality of LEDs. In an example implementation of the present subject matter, the width of each of the plurality of electrical connections is predefined to control brightness of a corresponding LED from amongst the plurality of LEDs.

Although implementations of the present subject matter have been described in language specific to methods and/or structural features, it is to be understood that the present subject matter is not limited to the specific methods or features described. Rather, the methods and specific features are disclosed and explained as example implementations of the present subject matter.

1. A backlight keyboard comprising:
a substrate;
a plurality of Light Emitting Diodes (LEDs) disposed of the substrate, to backlight the backlight keyboard;
a printed circuit disposed on the substrate, wherein the printed circuit comprises of a plurality of electrical connections to provide electric current to the plurality of LEDs, and wherein width of each of the plurality of electrical connections is predefined to control brightness of a corresponding LED from amongst the plurality of LEDs.

2. The backlight keyboard as claimed in claim 1, wherein the printed circuit is made of one of conductive polymer, silver nanowire, carbon nanotube and graphene.

3. The backlight keyboard as claimed in claim 2, wherein the conductive polymer is one of a poly (3,4-ethylenedioxythiophene) polystyrene sulfonate, Polyacetylene, and Polyaniline.

4. The backlight keyboard as claimed in claim 1, further comprising a reflector surface, disposed below the substrate to reflect light emitted by the plurality of LEDs.

5. The backlight keyboard as claimed in claim 1, further comprising a light guide plate disposed over the printed circuit and the plurality of LEDs.

6. The backlight keyboard as claimed in claim 1, wherein the width of each of the plurality of electrical connections corresponds to an electrical resistance of the corresponding electrical connection.

7. The backlight keyboard as claimed in claim 1, wherein the, plurality of LEDs is one of an edge-lit LED, a direct LED, and an organic light-emitting diode (OLED).

8. A method of fabricating lighting units for a backlight keyboard, the method comprising:
attaching a plurality of LEDs on a substrate of the backlight keyboard, wherein the plurality of LEDs is to backlight the keyboards and
printing a plurality of electrical connections of predefined widths on the substrate to form a printed circuit to provide electrical current to the plurality of LEDs, wherein width of each of the plurality of electrical connections is predefined to control brightness of a corresponding LED from amongst the plurality of LEDs.

9. The method as claimed in claim 8, wherein the printing is done by one of a screen printing technique, a ultra-violet (UV) based imprinting technique, an ink-jet printing technique, a rotogravure printing technique, 3D printing technique, and a laser engraving technique.

10. The method as claimed in claim 8, wherein the method comprises disposing the substrate onto a reflector surface to reflect light emitted by the plurality of LEDs.

11. The method as claimed in claim 8, wherein the method further comprises disposing a light guide plate over the printed circuit and the plurality of LEDs.

12. The method as claimed in claim 8, wherein the method further comprises forming a light scattering pattern over a light guide plate, wherein the light guide plate is disposed over the printed circuit and the plurality of LEDs.

13. The method as claimed in claim 12, wherein the forming is done by one of a screen printing technique, a ultra-violet (UV) based imprinting technique, an ink-jet printing technique, a rotogravure printing technique, 3D printing technique, and a laser engraving technique.

14. A lighting unit for backlighting a keyboard, the lighting unit comprising:
a substrate;
a plurality of LEDs disposed on the substrate; and
a plurality of electrical connections to provide electric current to the plurality of LEDs, wherein width of each of the plurality of electrical connections is predefined to control brightness of a corresponding LED from amongst the plurality of LEDs.

15. The lighting unit as claimed in claim 14, wherein the plurality of electrical connections is printed onto the substrate by one of a screen printing technique, a ultra-violet (UV) based imprinting technique, an ink jet printing technique, a rotogravure printing technique, 3D printing technique, and a laser engraving technique.
